(19) United States
(12) Patent Application Publication
(10) Pub. No.: US 2026/0307924 A1
(43) Pub. Date: Oct. 8, 2026

(54) FEEDER AND FEEDER MANAGING SYSTEM

(71) Applicant: FUJI CORPORATION, Chiryu (JP)

(72) Inventors: Daiki SUZUKI, Toyokawa-shi (JP); Hiroki MURASE, Nagoya-shi (JP)

(73) Assignee: FUJI CORPORATION, Chiryu (JP)

(21) Appl. No.: 19/481,762

(22) PCT Filed: Jun. 16, 2023
(86) PCT No.: PCT/JP2023/022502

§ 371 Date: Nov. 5, 2025

(51) Int. Cl. B65H 16/02

(52) U.S. Cl. CPC B65H 16/02; B65H 2557/23

(57) ABSTRACT

A feeder includes a feeder main body that includes a conveyance path configured to convey and support a carrier tape, a reel housing portion that is provided in the feeder main body and is configured to rotatably house a tape reel around which the carrier tape is wound, a housing width change mechanism configured to change, according to a reel width of the tape reel, a reel housing width for housing the tape reel in the reel housing portion, and an information update section configured to update feeder information in association with feeder identification information to information including the reel width or the reel housing width changed by the housing width change mechanism.

### TECHNICAL FIELD

The present description relates to a feeder and a feeder management system.

### BACKGROUND ART

In the conventional art, a feeder is known in which a displacement mechanism causing a tape reel around which a carrier tape is wound to move in a reel width direction is included (for example, refer to Patent Literature 1). The feeder includes a feeder main body having a conveyance path configured to convey and support the carrier tape, and a reel housing portion that is provided in the feeder main body and is configured to rotatably house the tape reel. The displacement mechanism causes the reel housing portion to move in the reel width direction with respect to the feeder main body to cause the tape reel to move in the reel width direction integrally with the reel housing portion. Therefore, it is possible to change, by the displacement mechanism, a reel width direction position of the reel housing portion with respect to the feeder main body and the tape reel housed in the reel housing portion.

In the feeder, when a reel housing width of the reel housing portion is narrow, the same number of feeders as the number of slots can be set on a feeder set table of a component mounter. Further, when the reel housing width of the reel housing portion is wide, the reel width direction position of the reel housing portion or the tape reel in each feeder is appropriately selected to enable a slot into which the feeder is inserted on the feeder set table of the component mounter to be set to an appropriate pitch. Therefore, it is possible to provide as many feeders as possible on the feeder set table.

### CITATION LIST

### Patent Literature

Patent Literature 1: Japanese U.S. Pat. No. 6,437,010

### BRIEF SUMMARY

### Technical Problem

For example, there is an automatic conveyance system that automatically inserts and removes a feeder into and from a component mounter, a transport device that automatically transports a feeder between a storage device and a component mounter, or the like. In such an automatic system, in order to appropriately insert and remove the feeder into and from the slot of the component mounter, the storage device, or the transport device in accordance with the reel housing width of the reel housing portion of the feeder as described above, the reel housing width of the reel housing portion, a tape width direction position of the tape reel housed in the reel housing portion, a reel width, and the like need to be in association with feeder identification information of each feeder. However, in the feeder described in Patent Literature 1, feeder information in association with the feeder identification information is not updated to information including the reel housing width of the reel housing portion and the like. For this reason, manageability of the feeder is deteriorated, so that the feeder may become incompatible with the automatic system.

An object of the present description is to provide a feeder capable of improving manageability by associating a reel housing width of a reel housing portion in which a tape reel is housed and a reel width of the tape reel in the feeder with feeder identification information, and a feeder management system capable of appropriately controlling setting of the feeder into various slots.

### Solution to Problem

The present description discloses a feeder including a feeder main body that includes a conveyance path that conveys and supports a carrier tape, a reel housing portion that is provided in the feeder main body and is configured to rotatably house a tape reel around which the carrier tape is wound, a housing width change mechanism configured to change, according to a reel width of the tape reel, a reel housing width for housing the tape reel in the reel housing portion, and an information update section configured to update feeder information in association with feeder identification information to information including the reel width or the reel housing width changed by the housing width change mechanism.

According to the present disclosure, it is possible to associate the reel housing width of the reel housing portion in which the tape reel is housed and the reel width of the tape reel in the feeder with the feeder identification information, and thus to improve the manageability of the feeder.

### BRIEF DESCRIPTION OF DRAWINGS

FIG. 1 is a perspective view of a feeder set table of a component mounter in which a feeder according to an embodiment is set.

FIG. 2 is a perspective view of a tape reel around which a carrier tape is wound.

FIG. 3 is a side view of the feeder according to the embodiment.

FIGS. 4A and 4B are views illustrating an example of a housing width change mechanism that changes a reel housing width in the feeder according to the embodiment.

FIG. 5 is a rear view of a narrow-width state in which the reel housing width is narrow in the feeder according to the embodiment.

FIG. 6 is a rear view of a wide-width state in which the reel housing width is wide in the feeder according to the embodiment.

FIG. 7 is a configuration diagram of a feeder management system that manages the feeder according to the embodiment.

FIGS. 8A and 8B are views illustrating an example of a method of detecting the reel housing width in the feeder according to the embodiment.

FIG. 9 is a view illustrating an example of the housing width change mechanism that changes the reel housing width in the feeder according to a modified embodiment.

FIG. 10 is a configuration diagram of the feeder management system that manages the feeder of the modified embodiment shown in FIG. 9.

FIG. 11 is a diagram showing a state in which the feeder having a narrow reel housing width is set in a slot, in order to describe an effect of the feeder of the modified embodiment shown in FIG. 9.

FIG. 12 is a diagram showing a state in which the feeder having a wide reel housing width is set in a slot, in order to describe an effect of the feeder of the modified embodiment shown in FIG. 9.

### DESCRIPTION OF EMBODIMENTS

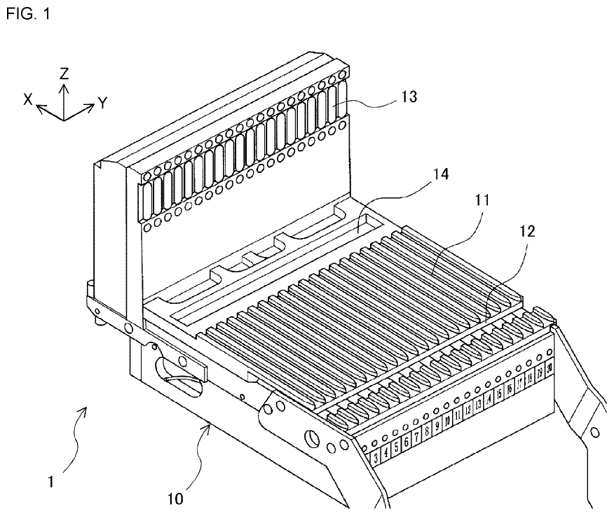

Hereinafter, an embodiment of a feeder and a feeder management system according to the present disclosure will be described with reference to FIGS. 1 to 12.

### 1. Configuration of Component Mounter for Setting Feeder

Feeder 20 according to the embodiment is a device that supplies, to component supply position S, a component to be mounted on a board. Feeder 20 is detachably incorporated in component mounter 1. Component mounter 1 is provided on a board production line, and picks up by suction or grips a component at component supply position S to transfer the component to the board.

Component mounter 1 includes feeder set table 10. Feeder set table 10 is a table on which multiple feeders 20 are set. As shown in FIG. 1, feeder set table 10 has slots 11. Slot 11 is a gap portion into which feeder 20 is detachably inserted. Slot 11 is formed in a shape capable of vertically supporting feeder 20. Multiple slots 11 are disposed side by side in feeder set table 10. The number of slots 11 in feeder set table 10 is, for example, 20.

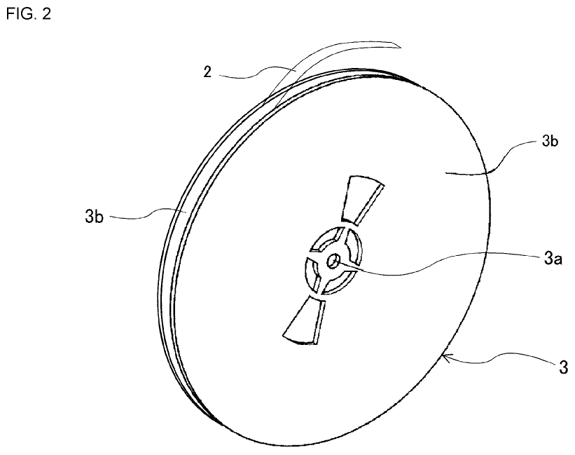

As shown in FIG. 1, feeder set table 10 has clamp groove 12 into which feeder 20 is fitted, and connector 13 to which power line and signal line of feeder 20 are connected, in correspondence with each slot 11. Further, feeder set table 10 has tape discharge port 14 for discharging a waste tape of carrier tape 2 (refer to FIG. 2) which houses components.

Feeder 20 can convey carrier tape 2. The components serving as supply targets by feeder 20 are electronic components such as transistors, diodes, and resistors constituting an electronic circuit. Examples of the component include a minute, such as a 0201 size (0.2 mm×0.1 mm), component and a large component such as a capacitor.

### 2. Configuration of Carrier Tape and Tape Reel

Carrier tape 2 is formed in an elongated shape. In general, carrier tape 2 has a tape width of, for example, 4 mm, 8 mm, 12 mm, 16 mm, or 24 mm, which is defined in advance as a standard. Carrier tape 2 has a base tape having component housing portions that are arranged at predetermined intervals in a tape longitudinal direction to house the components, and a cover tape that closes a component takeout opening of the base tape.

The component is housed in the component housing portion when the cover tape is bonded to the base tape, and is exposed from the component housing portion when the cover tape is peeled off from the base tape to be capable of being taken out to the outside. Carrier tape 2 may be an embossed tape whose component housing portion of the base tape protrudes downward, or may be a paper tape whose surface is provided with a groove-shaped component housing portion. Carrier tape 2 is wound around tape reel 3.

Tape reel 3 is formed in a disk shape. Tape reel 3 is made of, for example, resin or cardboard. Tape reel 3 has holding hole 3a and flange portion 3b. Holding hole 3a is a through hole that penetrates in a rotation axis direction, which is necessary for holding tape reel 3 in feeder 20. Flange portion 3b is a portion extending in a disk shape around holding hole 3a. Holding hole 3a is disposed at an axial center of flange portion 3b, and extends in a reel width direction (hereinafter, referred to as reel width direction Y) that matches tape width direction Y of carrier tape 2 wound around tape reel 3.

Pair of flange portions 3b is provided apart from each other in reel width direction Y. Pair of flange portions 3b is disposed and formed to sandwich wound carrier tape 2. Pair of flange portions 3b is separated from each other in reel width direction Y such that a gap equal to or larger than a tape width of carrier tape 2 serving as a wound target is formed. As tape reel 3, in general, a tape reel is used in which a distance by which pair of flange portions 3b is separated in reel width direction Y (that is, reel width) is predetermined as a standard (for example, JIS standard), but a tape reel other than the standard may be used.

### 3. Configuration of Feeder

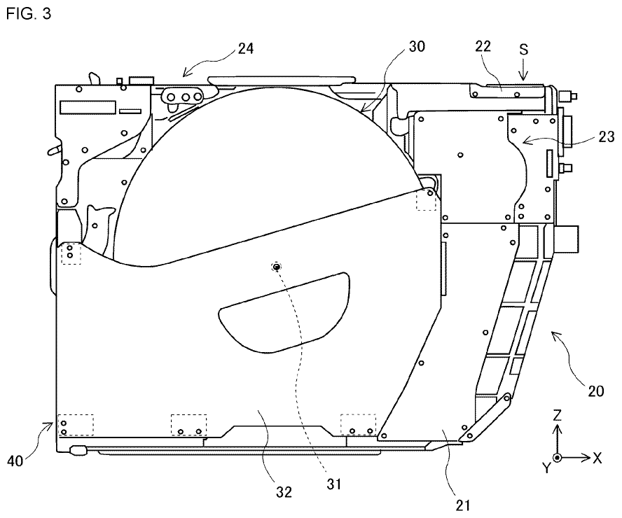

Feeder 20 is, for example, a cassette-type tape feeder capable of housing tape reel 3. As shown in FIG. 3, feeder 20 includes feeder main body 21, reel housing portion 30, housing width change mechanism 40, tape guide 22, tape conveyance mechanism 23, and cover tape discharge mechanism 24.

Feeder main body 21 is a main body member including a frame portion to which reel housing portion 30, housing width change mechanism 40, tape guide 22, tape conveyance mechanism 23, and cover tape discharge mechanism 24 are attached and an attachment portion attached to slot 11 of component mounter 1. Feeder main body 21 is formed in a flat shape that is attachable to and detachable from slot 11 of component mounter 1.

Feeder main body 21 has a conveyance path that conveys and supports carrier tape 2. The conveyance path is in contact with a lower surface of carrier tape 2, and supports carrier tape 2 from below. The conveyance path extends along tape conveyance direction X, and supports carrier tape 2 at upper ends of a horizontal wall facing upward and standing walls on both sides in tape width direction Y.

Reel housing portion 30 is a portion that rotatably houses tape reel 3. Reel housing portion 30 is provided in feeder main body 21. Reel housing portion 30 forms a housing space for housing tape reel 3. Reel housing portion 30 is configured to detachably load tape reel 3. As shown in FIG. 3, reel housing portion 30 has reel holding shaft 31 and cover 32.

Reel holding shaft 31 is a shaft portion that rotatably supports tape reel 3 on a side of feeder main body 21. Reel holding shaft 31 is provided on an inner surface of a side wall of feeder main body 21 on one side facing reel width direction Y (for example, side wall located on a left side when feeder 20 faces from an upstream side to a downstream side in tape conveyance direction X). Reel holding shaft 31 protrudes, on a housing space side, in a cylindrical shape from the inner surface of the side wall of feeder main body 21.

Cover 32 is a portion that covers tape reel 3, which is housed in reel housing portion 30 and supported by reel holding shaft 31, from an outer side. Cover 32 is formed in a plate shape. Cover 32 is disposed on any one side of feeder main body 21 in reel width direction Y (for example, right side when feeder 20 faces from the upstream side to the downstream side in tape conveyance direction X). That is, cover 32 is disposed on a side of side wall that faces the side wall of feeder main body 21, which is provided with reel holding shaft 31, in reel width direction Y via the housing space. Cover 32 covers at least a part of a flange surface of flange portion 3b of tape reel 3 (for example, lower part thereof as shown in FIG. 3) from the outer side in reel width direction Y. Reel holding shaft 31 may be provided on a back surface of cover 32.

Cover 32 is openable and closable with respect to feeder main body 21. Specifically, cover 32 can be switched between a closed state in which the housing space is closed integrally with the side wall of feeder main body 21 and an open state in which the housing space is opened away from the side wall of feeder main body 21. Cover 32 is opened and closed by, for example, rotation by a hinge or sliding along a rail with respect to feeder main body 21. Tape reel 3 is attached to and detached from reel housing portion 30 in the open state of cover 32.

Housing width change mechanism 40 is a mechanism that changes a reel housing width for housing tape reel 3 in reel housing portion 30. The reel housing width is a length of the housing space in reel housing portion 30 in reel width direction Y, that is, a distance between the inner surface of the side wall of feeder main body 21 and the back surface of cover 32. Housing width change mechanism 40 moves cover 32 of reel housing portion 30 in reel width direction Y, which is tape width direction Y, with respect to feeder main body 21 to change the reel housing width.

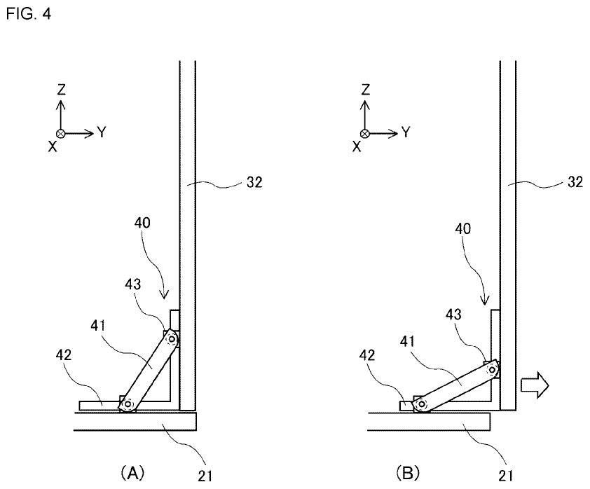

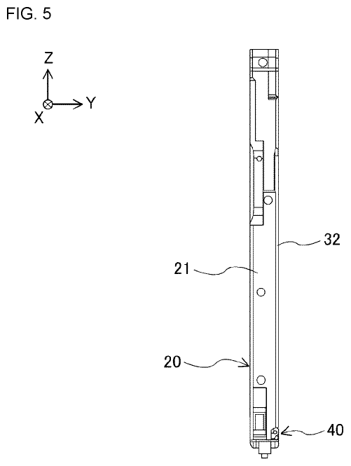

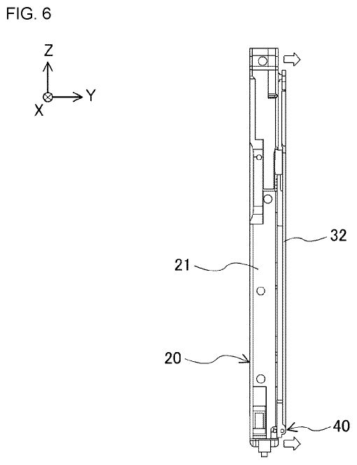

Housing width change mechanism 40 can change the reel housing width between a narrow-width state in which the reel housing width is relatively narrow (state shown in FIG. 4A and FIG. 5) and a wide-width state in which the reel housing width is relatively wide (state shown in FIG. 4B and FIG. 6). The reel housing width in the narrow-width state may correspond to tape reel 3 of a general standard. Further, the reel housing width in the wide-width state may correspond to tape reel 3 other than the standard such as the cardboard, or may be a width larger than a pitch of slots 11 of component mounter 1 (however, smaller than twice the pitch of slots 11). Housing width change mechanism 40 may change the reel housing width in two stages between the narrow-width state and the wide-width state, or may change the reel housing width in multiple stages or linearly.

Housing width change mechanism 40 may be any mechanism that can move cover 32 in reel width direction Y with respect to feeder main body 21, and may be, for example, a link mechanism that connects feeder main body 21 and cover 32. Further, housing width change mechanism 40 may move, manually by a worker, cover 32 in reel width direction Y with respect to feeder main body 21, or may move, by motor drive, cover 32 in reel width direction Y with respect to feeder main body 21.

Housing width change mechanism 40 changes the reel housing width in accordance with the reel width of tape reel 3. Housing width change mechanism 40 may automatically change the reel housing width in accordance with the reel width of tape reel 3 when tape reel 3 is housed in reel housing portion 30, or may manually change the reel housing width in accordance with the reel width of tape reel 3 scheduled to be housed in reel housing portion 30.

Further, housing width change mechanism 40 may have a guide section that guides cover 32 during movement in order to cause cover 32 to move smoothly. Further, housing width change mechanism 40 may have a biasing member, such as a spring, that biases cover 32 to the side of the side wall of feeder main body 21 to hold the narrow-width state in a normal state. Furthermore, housing width change mechanism 40 may have a lock mechanism that causes a position of cover 32 in reel width direction Y with respect to feeder main body 21 to lock at any position (for example, any one of the narrow-width state and the wide-width state).

In a structure in which housing width change mechanism 40 is the link mechanism, for example, as shown in FIGS. 4A and 4B, housing width change mechanism 40 has link 41, slider 42, and slide joint 43. Link 41 is a member that is formed in an elongated shape and has a first end portion swingably supported by feeder main body 21 and a second end portion swingably supported by cover 32. Slider 42 is a member integrated with cover 32. Slide joint 43 is a member that is slidable along the back surface of cover 32, which is perpendicular to reel width direction Y with respect to slider 42. In housing width change mechanism 40, when link 41 swings, cover 32 moves in reel width direction Y while slide joint 43 slides along the back surface of cover 32.

Tape guide 22 is a guide member that guides carrier tape 2 to be conveyed on the conveyance path. Tape guide 22 is disposed above the conveyance path of carrier tape 2. Tape guide 22 is detachably mounted on the downstream side and an upper side of feeder main body 21 in tape conveyance direction X. Tape guide 22 is formed to have a U-shaped cross section to be able to abut on an upper surface and a side surface of carrier tape 2. Carrier tape 2 is guided in contact with an upper wall and a side wall of tape guide 22 when being conveyed in tape conveyance direction X. Tape guide 22 has a fold-back portion that folds back the cover tape peeled off from the base tape of carrier tape 2 to a side opposite to the base tape thereof.

Tape conveyance mechanism 23 is a mechanism that conveys carrier tape 2. Tape conveyance mechanism 23 has a disk plate-shaped sprocket that conveys carrier tape 2 by rotation, and a drive motor such as an electric motor that generates power for rotating the sprocket. The sprocket and the drive motor are disposed below the conveyance path. When the drive motor is driven in a state where engagement protrusion of the sprocket is inserted into a feed hole of carrier tape 2, carrier tape 2 is conveyed in accordance with the driving of the drive motor.

It is preferable that the sprocket of tape conveyance mechanism 23 is disposed close to a peel-off position of the cover tape or component supply position S in feeder 20 to prevent a positional deviation in tape width direction Y in carrier tape 2. Further, it is preferable that the drive motor not only rotates the sprocket only in a direction in which carrier tape 2 is fed forward in tape conveyance direction X but also rotates the sprocket in a direction opposite to the forward feeding direction, for example, to adjust a position of carrier tape 2 in tape conveyance direction X or improve positioning accuracy.

Cover tape discharge mechanism 24 is a mechanism that discharges the cover tape peeled off from the base tape of carrier tape 2 to the outside of feeder main body 21. Cover tape discharge mechanism 24 lowers the cover tape, which is peeled off from the base tape on the upstream side of component supply position S of feeder 20 in tape conveyance direction X and folded back to pass above the conveyance path, along a side surface of feeder main body 21 to discharge the cover tape. Cover tape discharge mechanism 24 has a winding gear, a winding motor, or the like that rotates in synchronization with the conveyance of carrier tape 2 in tape conveyance direction X to discharge the cover tape.

In feeder 20, carrier tape 2 is inserted into a tape inlet of feeder main body 21 and supported by the conveyance path, and is set such that the feed hole of carrier tape 2 is engaged with the sprocket of tape conveyance mechanism 23 on a tape outlet side. Further, the cover tape of carrier tape 2 is completely peeled off from the base tape starting from the fold-back portion on the upstream side of component supply position S in tape conveyance direction X, and is set to engage with the winding gear along a predetermined discharge path.

When the sprocket rotates, carrier tape 2 is fed from the upstream side to the downstream side in tape conveyance direction X, and the cover tape is discharged toward the outer side of feeder 20 while being peeled off from the base tape in conjunction with the conveyance of carrier tape 2. In this case, the component in the component housing portion of carrier tape 2 is exposed to be taken out. After the exposure, the component reaches component supply position S, and then is held by a suction nozzle or the like of component mounter 1 to be transferred to an electronic board.

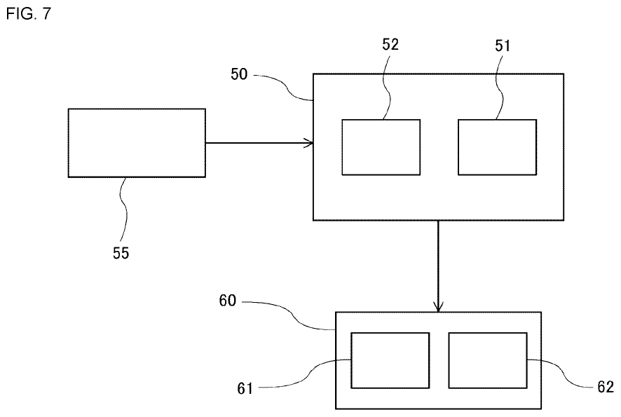

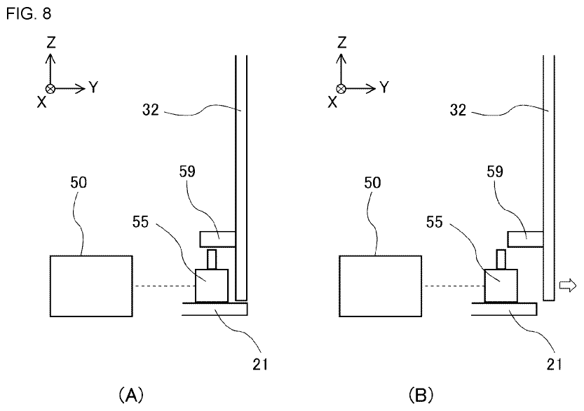

Feeder 20 further includes control device 50 (refer to FIGS. 7, 8A, and 8B). Control device 50 is a device that controls the operation of feeder 20 and manages feeder information of feeder 20. Control device 50 is configured primarily of a microcomputer. Control device 50 is built into feeder 20. As shown in FIG. 7, control device 50 includes information update section 51 that updates the feeder information, and width detection section 52 that detects the reel width of tape reel 3 or the reel housing width of reel housing portion 30.

Sensor 55 is connected to control device 50. Sensor 55 is a portion that outputs an electrical signal corresponding to the reel width of tape reel 3 or the reel housing width of reel housing portion 30. Specifically, sensor 55 outputs an electrical signal in accordance with a reel width direction position of cover 32 with respect to feeder main body 21. For example, as shown in FIGS. 8A and 8B, sensor 55 is attached and fixed to feeder main body 21, and outputs an electric signal corresponding to separation or contact of dog 59 integrated with cover 32.

For example, sensor 55 outputs an ON signal when the reel housing width is in the narrow-width state as shown in FIG. 8A, and outputs an OFF signal when the reel housing width is in the wide-width state as shown in FIG. 8B. The output signal of sensor 55 is supplied to control device 50.

Sensor 55 may be a contact type sensor that outputs a signal in accordance with the reel width direction position of cover 32 by contact with dog 59, or may be a non-contact type sensor, such as a proximity sensor or a photoelectric sensor, that outputs a signal in accordance with the reel width direction position of cover 32 by non-contact with dog 59.

Width detection section 52 of control device 50 detects the reel width direction position of cover 32 with respect to feeder main body 21 based on the output signal of sensor 55 to detect the reel housing width of reel housing portion 30 and the reel width of tape reel 3.

When width detection section 52 detects the reel housing width of reel housing portion 30 and the reel width of tape reel 3, control device 50 updates the feeder information in information update section 51. The feeder information is in association with identification information unique to the feeder (hereinafter, referred to as feeder identification information) determined for each feeder 20, and includes at least the reel housing width of reel housing portion 30 in feeder main body 21. The feeder information may include, for example, a type and identification information of tape reel 3 housed in reel housing portion 30, the reel width of tape reel 3, a type and tape width of carrier tape 2, and a type and identification information of tape guide 22.

For example, in a case where tape reel 3 housed in reel housing portion 30 of feeder main body 21 is exchanged from a narrow-width tape reel to a wide-width tape reel, information update section 51 links the reel housing width or the reel width detected by width detection section 52 to the feeder identification information in association with each other to update the feeder information. The detection by width detection section 52 or the update by information update section 51 may be performed at a timing when tape reel 3 is housed in reel housing portion 30, may be consecutively performed at regular time intervals after the housing, or may be performed at a timing of a collation process in an off-line setup device.

### 4. Configuration of Feeder Management System for Managing Feeder

Control device 50 of feeder 20 is connected to feeder management system 60. Feeder management system 60 is a system constituting a higher-level device positioned above feeder 20. Feeder management system 60 is a management device such as component mounter 1 including feeder set table 10 to which multiple feeders 20 can be set or a host computer that manages component mounter 1 and feeder 20.

Control device 50 transmits the feeder information updated by information update section 51 to feeder management system 60. The transmission of the feeder information from control device 50 to feeder management system 60 may be performed after the feeder information is updated, for example, at the timing of the collation process in the off-line setup device.

Feeder management system 60 includes storage section 61 and control section 62. Feeder management system 60 can receive the feeder information transmitted from control device 50 of feeder 20. In a case where feeder management system 60 receives the feeder information, storage section 61 stores the feeder information after being updated by information update section 51 of feeder 20.

After the feeder information is stored in storage section 61, control section 62 performs management and various controls related to feeder 20 based on the feeder information. For example, control section 62 controls setting of feeder 20 into a slot of a device such as a transport device that transports feeder 20 or a storage device that stores feeder 20, including the setting of feeder 20 into slot 11 of component mounter 1. Specifically, the slot into which feeder 20 is set is changed, according to the reel housing width included in the feeder information, within a range in which interference with feeder 20 set in another slot is avoided.

### 5. Updating of Feeder Information and Effects of Updating

For example, when the component in carrier tape 2 loaded in feeder 20 is empty or the component is not used in feeder 20, tape reel 3 housed in reel housing portion 30 is exchanged with new tape reel 3. Attachment and detachment of tape reel 3 in feeder 20 and housing of tape reel 3 in new feeder 20 are performed by the worker in, for example, an off-line setup area.

In a case where the reel width of tape reel 3 housed in reel housing portion 30 is relatively narrow, the reel housing width of reel housing portion 30 is in the narrow-width state due to the movement of cover 32 by housing width change mechanism 40, after or before tape reel 3 is housed in reel housing portion 30. In this case, sensor 55 outputs the ON signal, width detection section 52 detects the reel housing width in the narrow-width state, and information update section 51 associates the reel housing width in the narrow-width state with the feeder identification information to update the feeder information. The feeder information is transmitted to feeder management system 60, and stored in storage section 61.

When the reel width of tape reel 3 housed in reel housing portion 30 is relatively wide, the reel housing width of reel housing portion 30 is in the wide-width state due to the movement of cover 32 by housing width change mechanism 40, after or before tape reel 3 is housed in reel housing portion 30. In this case, sensor 55 outputs the OFF signal, width detection section 52 detects the reel housing width in the wide-width state, and information update section 51 associates the reel housing width in the wide-width state with the feeder identification information to update the feeder information. The feeder information is transmitted to feeder management system 60, and stored in storage section 61.

After the feeder information is stored in storage section 61 as described above, control section 62 of feeder management system 60 controls the setting of feeder 20 into the slot (including slot 11 of component mounter 1) of at least one device of component mounter 1, the transport device, and the storage device, based on the feeder information.

The pitch of the slots of component mounter 1, the transport device, and the storage device is preferably a minimum pitch such that a large number of feeders 20 can be efficiently arranged. When the slot pitch is the minimum pitch, it is possible to arrange a large number of feeders in a limited space, and thus achieve space saving in mounting feeder 20 on the device.

When feeder 20 houses tape reel 3 having a narrow reel width in reel housing portion 30, the reel housing width of reel housing portion 30 is in the narrow-width state. In this case, it is possible to consecutively set feeders 20 having the reel housing width in the narrow-width state in multiple slots disposed side by side in feeder set table 10 or the like. On the other hand, when feeder 20 houses tape reel 3 having a wide reel width in reel housing portion 30, the reel housing width of reel housing portion 30 is in the wide-width state. In this case, it is not possible to consecutively set feeders 20 having the reel housing width in the wide-width state in the multiple slots disposed side by side in feeder set table 10 or the like, and feeders 20 can only be set in every other slot among the multiple slots.

Control section 62 controls, for example, setting of feeder 20 from the off-line setup device into the slot of the transport device and setting of feeder 20 from the transport device into slot 11 of component mounter 1, based on the feeder information of feeder 20 stored in storage section 61. Specifically, the slot into which feeder 20 is set is changed, according to the reel housing width included in the feeder information, within a range in which interference with feeder 20 set in another slot is avoided.

For example, when the feeder information stored in storage section 61 for target feeder 20 includes information on the reel housing width in the narrow-width state, the setting control of feeder 20 is performed such that setting into any slot (however, limited to an empty slot) among the multiple slots is allowed. On the other hand, when the feeder information stored in storage section 61 for target feeder 20 includes information on the reel housing width in the wide-width state, the setting control of feeder 20 is performed such that two empty slots among the multiple slots are consecutive and setting to one of the two consecutive empty slots is allowed.

The empty slot in which feeder 20 is allowed to be set, of the two consecutive empty slots, is a slot on a side opposite to a side where cover 32 is present in feeder 20 in reel width direction Y, of the two empty slots. Further, in this case, a remaining empty slot is a slot in which the setting of feeder 20 is prohibited. This is to avoid interference between feeders 20 to be inserted into adjacent slots.

Further, in a case where tape reel 3 is taken out from reel housing portion 30 of feeder 20 after the feeder information is updated, information update section 51 separates the information on the reel housing width from the feeder identification information to delete and update the feeder information. A timing of the deletion and update of the feeder information may be after tape reel 3 is actually taken out from reel housing portion 30, or may be after feeder management system 60 or the like determines that tape reel 3 housed in reel housing portion 30 is not used in feeder 20.

In a case where information update section 51 of feeder 20 deletes and updates the feeder information as described above, feeder management system 60 deletes the feeder information of feeder 20 stored in storage section 61. Specifically, the information on the reel housing width in association with the feeder identification information of feeder 20 is deleted.

As described above, in the present embodiment, in a case where tape reel 3 is housed in reel housing portion 30 of feeder 20, the information on the reel housing width of reel housing portion 30 can be associated with the feeder identification information of feeder 20 to update the feeder information. Further, the updated feeder information can be transmitted to feeder management system 60 and stored in storage section 61. After the feeder information related to feeder 20 is stored in storage section 61, it is possible to control the setting of feeders 20 into the slots of various devices based on the reel housing width in association with the feeder identification information in the feeder information.

With this configuration, it is possible to achieve, with a slot structure in which a large number of feeders 20 can be disposed in various devices including component mounter 1 having slots 11, the setting of feeders 20 into these slots within a range in which the interference between feeders 20 does not occur in accordance with the reel housing width.

Therefore, for example, even in a case where carrier tapes 2 of the same type and the same tape width are wound not on tape reel 3 within the standard but on tape reel 3 made of, for example, a cardboard, having the reel width larger than the standard, it is possible to house wide-width tape reel 3 in reel housing portion 30 of feeder 20, and set feeder 20 housing wide-width tape reel 3 into an optimal slot.

Further, in a case where carrier tape 2 is wound around tape reel 3 in the narrow-width state, unlike a case where carrier tape 2 is wound around tape reel 3 in the wide-width state, it is possible to avoid the limitation in the number of feeders 20 capable of being mounted on various devices, and thus reduce the influence on the number of feeders 20 to be mounted.

Furthermore, in a case where tape reel 3 is taken out from reel housing portion 30 of feeder 20, the feeder information is deleted and updated. Therefore, it is possible to associate the reel housing width with the feeder identification information only for a necessary period. Since unnecessary continuation of the association over a long period can be avoided, it is possible to avoid the erroneous setting of feeders 20 into the slots of various devices as much as possible.

### 6. Modified Embodiment

In the above embodiment, dog 59 is integrally provided on cover 32 of reel housing portion 30 of feeder 20, sensor 55 is caused to output the electric signal corresponding to the separation or contact of dog 59, and width detection section 52 detects the reel width direction position of cover 32 with respect to feeder main body 21 to detect the reel housing width of reel housing portion 30. However, the present disclosure is not limited thereto. With image processing using a camera, the reel width direction position of cover 32 with respect to feeder main body 21 may be detected to detect the reel housing width of reel housing portion 30, or the reel width of tape reel 3 when tape reel 3 is housed in reel housing portion 30 may be detected.

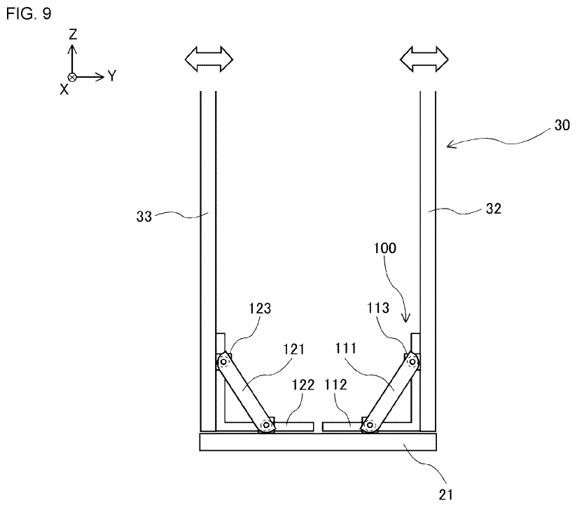

In the above embodiment, reel housing portion 30 of feeder 20 includes cover 32 disposed on a first side of feeder main body 21 in reel width direction Y. However, the present disclosure is not limited thereto. As shown in FIG. 9, reel housing portion 30 may include cover 32, and cover 33 that is paired with cover 32 and is disposed on a second side of feeder main body 21 in reel width direction Y.

In the modified embodiment as shown in FIG. 9, housing width change mechanism 40 moves cover 32 and cover 33 in reel width direction Y with respect to feeder main body 21 to change the reel housing width of reel housing portion 30. In this modified embodiment, the reel housing width of reel housing portion 30 can be changed to a narrowest state at a narrowest width, a widest state at a widest width, and an intermediate state between the narrowest state and the widest state. Further, the intermediate state has two patterns, that is, a first pattern when an accommodating space is on a right-hand side with respect to feeder main body 21 and a second pattern when the accommodating space is on a left-hand side with respect to feeder main body 21.

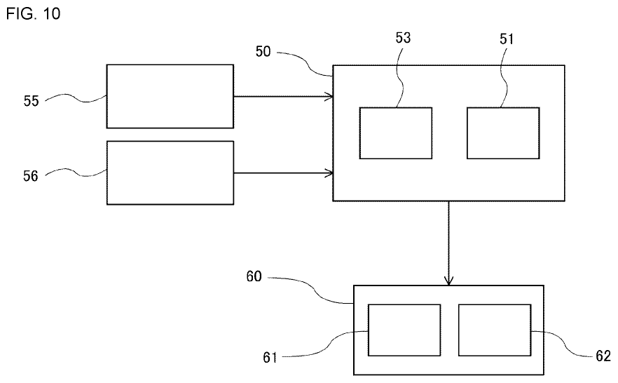

Furthermore, as shown in FIG. 10, sensor 55 that performs the signal output in accordance with the reel width direction position of cover 32 and sensor 56 that performs the signal output in accordance with the reel width direction position of cover 33 are provided as the sensors, and control device 50 includes information update section 51 and cover position detection section 53 that detects the reel width direction position of each of covers 32 and 33 with respect to feeder main body 21. When cover position detection section 53 detects the reel width direction position of each of covers 32 and 33 with respect to feeder main body 21, a distance between the reel width direction positions of both covers 32 and 33 can be calculated as the reel housing width of reel housing portion 30.

Information update section 51 associates, with the feeder identification information, the reel width direction position of cover 32, the reel width direction position of cover 33, and the reel housing width of reel housing portion 30, which are detected by cover position detection section 53, to update the feeder information. The feeder information is transmitted to feeder management system 60, and stored in storage section 61. Control section 62 of feeder management system 60 controls the setting of feeders 20 into the slots of various devices including component mounter 1, based on the feeder information including the reel width direction position of cover 32, the reel width direction position of cover 33, and the reel housing width of reel housing portion 30.

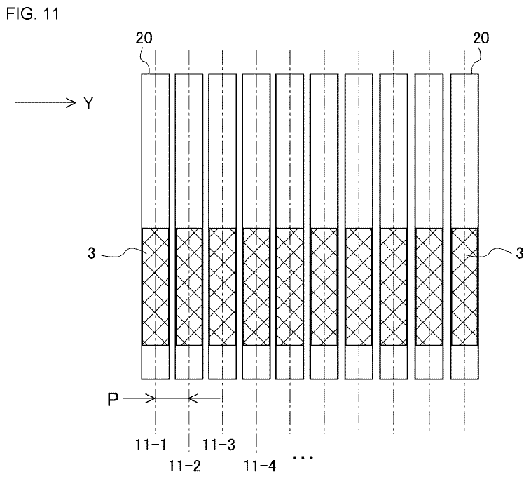

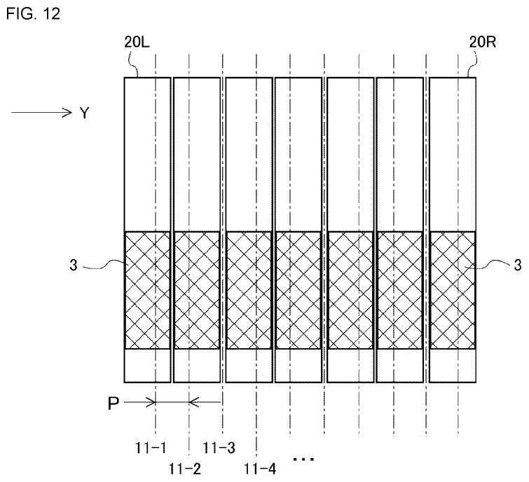

For example, in a structure in which the pitch of slots 11 of component mounter 1 in reel width direction Y is pitch P in which feeders 20 having the reel housing width in the narrowest state can be consecutively set in two slots 11 adjacent to each other as shown in FIG. 11 and feeders 20 having the reel housing width in the widest state cannot be consecutively set therein, there may be a case where feeders 20 having the reel housing width in the intermediate state can be set in two slots 11 adjacent to each other as shown in FIG. 12. Hereinafter, feeder 20 having the reel housing width in the intermediate state and having the housing space positioned on the left-hand side is referred to as left-hand side feeder 20L, and feeder 20 having the reel housing width in the intermediate state and having the housing space positioned on the right-hand side is referred to as right-hand side feeder 20R.

For example, as shown in FIG. 12, right-hand side feeder 20R can be set in slot 11 (second slot 11-2) adjacent, on a right side, to slot 11 (first slot 11-1) in which left-hand side feeder 20L is set, slot 11 (third slot 11-3) adjacent, on a right side, to second slot 11-2 is set as an empty slot, left-hand side feeder 20L can be set in slot 11 (fourth slot 11-4) adjacent, on a right side, to empty third slot 11-3, and the same setting designation is repeated thereafter.

In this modified embodiment, while left-hand side feeder 20L and right-hand side feeder 20R can be consecutively set in two slots 11 adjacent in reel width direction Y, slot 11 on a side opposite to these two slots 11 in reel width direction Y is set as an empty slot. That is, feeder 20 having the reel housing width in the intermediate state can be set not only in every other slot among multiple slots 11 arranged in reel width direction Y, but also in two slots 11 adjacent to each other among three slots 11 consecutive in reel width direction Y.

Therefore, it is possible to achieve, with the slot structure in which a large number of feeders 20 can be disposed in various devices including component mounter 1 having slots 11, the setting of feeders 20 into these slots 11 as many as possible within the range in which the interference between feeders 20 does not occur in accordance with the reel housing width.

In the above modified embodiment, reel housing portion 30 of feeder 20 includes two covers 32 and 33, which are disposed on both sides in reel width direction Y, and feeder 20 can be either left-hand side feeder 20L or right-hand side feeder 20R. However, the present disclosure is not limited thereto. Feeder 20 in which reel housing portion 30 has a cover on a first side in reel width direction Y and feeder 20 in which reel housing portion 30 has a cover on a second side in reel width direction Y may be used in a mixed manner, as feeder 20.

Furthermore, in the above embodiment, feeder 20 is the cassette-type tape feeder. However, the present disclosure is not limited thereto, and may be applied to a tape feeder other than the cassette-type tape feeder as long as feeder 20 can house tape reel 3.

It should be noted that the present disclosure is not limited to the above embodiments and modified embodiments, and various modifications can be made without departing from a gist of the present disclosure. Further, the present disclosure not only discloses the technical idea indicated by the citation relationship described in each claim as originally filed, but also discloses the technical idea in which the matters described in each claim are combined as appropriate.

### REFERENCE SIGNS LIST

1: component mounter, 2: carrier tape, 3: tape reel, 10: feeder set table, 11: slot, 20: feeder, 21: feeder main body, 30: reel housing portion, 31: reel holding shaft, 32, 33: cover, 40: housing width change mechanism, 50: control device, 51: information update section, 52: width detection section, 53: cover position detection section, 55,56: sensor, 59: dog, 60: feeder management system, 61: storage section, 62: control section, S: component supply position.

1. A feeder comprising:
a feeder main body that includes a conveyance path configured to convey and support a carrier tape;
a reel housing portion that is provided in the feeder main body and is configured to rotatably house a tape reel around which the carrier tape is wound;
a housing width change mechanism configured to change, according to a reel width of the tape reel, a reel housing width for housing the tape reel in the reel housing portion; and
an information update section configured to update feeder information in association with feeder identification information to information including the reel width or the reel housing width changed by the housing width change mechanism.

2. The feeder according to claim 1, further comprising:
a width detection section configured to detect the reel width of the tape reel housed in the reel housing portion or the reel housing width of the reel housing portion,
wherein the information update section is configured to associate the reel width or the reel housing width detected by the width detection section with the feeder identification information to update the feeder information.

3. The feeder according to claim 1,
wherein the reel housing portion includes a reel holding shaft that rotatably supports the tape reel, and a cover that covers, from an outer side, at least a part of flange surfaces of the tape reel supported by the reel holding shaft, and
the housing width change mechanism is configured to move at least the cover in a reel width direction with respect to the feeder main body to change the reel housing width.

4. The feeder according to claim 3,
wherein the cover includes a first cover disposed on the outer side of a first one of the flange surfaces of the tape reel and a second cover disposed on the outer side of a second one of the flange surfaces of the tape reel, and
the housing width change mechanism is capable of moving each of the first cover and the second cover in the reel width direction with respect to the feeder main body.

5. The feeder according to claim 4, further comprising:
a cover position detection section configured to detect a reel width direction position of each of the first cover and the second cover with respect to the feeder main body,
wherein the information update section is configured to associate, with the feeder identification information, the reel width direction position of the first cover and the reel width direction position of the second cover, which are detected by the cover position detection section, and the reel housing width that is a distance between both reel width direction positions to update the feeder information.

6. The feeder according to claim 1, wherein the information update section is configured to, in a case where the feeder information is updated and then the tape reel is taken out from the reel housing portion, delete and update the feeder information.

7. A feeder management system for managing the feeder according to claim 1, the feeder management system comprising:
a storage section configured to store the feeder information after being updated by the information update section, the feeder information being transmitted from the feeder; and
a control section configured to control setting of the feeder into a slot provided in at least one of a component mounter, a transport device, and a storage device, based on the feeder information stored in the storage section.

8. The feeder management system according to claim 7, wherein the control section is configured to change the slot into which the feeder is set, according to the reel width or the reel housing width in the feeder information stored in the storage section, within a range in which interference with another feeder set in another slot is avoided.
